(19) United States
(12) Patent Application Publication
(10) Pub. No.: US 2018/0267111 A1
(43) Pub. Date: Sep. 20, 2018

(54) METHOD FOR MONITORING A BATTERY

(71) Applicant: Robert Bosch GmbH, Stuttgart (DE)

(72) Inventors: Grzegorz PILATOWICZ, Aachen (DE); Christel SARFERT, Korntal-Muenchingen (DE); Juergen MOTZ, Steinheim An Der Murr (DE)

(21) Appl. No.: 15/762,474

(22) PCT Filed: Aug. 2, 2016
(86) PCT No.: PCT/EP2016/068383

§ 371 Date: Mar. 22, 2018

(30) Foreign Application Priority Data
Sep. 24, 2015 (DE) 10 2015 218 326.2

(51) Int. Cl. G01R 31/36; G01R 31/02; H02J 7/00

(52) U.S. Cl. CPC G01R 31/3679; G01R 31/3662; H02J 7/0029; G01R 31/3668; G01R 31/025; G01R 31/3648

(57) ABSTRACT

A method for monitoring a battery includes detecting at least one variable of the battery, analyzing the behavior of the variable over time to obtain a result, and identifying a fault of the battery in response to the result exceeding a threshold value.

### CROSS-REFERENCE TO RELATED APPLICATIONS

The present application is the national stage of International Pat. App. No. PCT/EP2016/068383 filed Aug. 2, 2016, and claims priority under 35 U.S.C. §119 to DE 10 2015 218 326.2, filed in the Federal Republic of Germany on Sep. 24, 2015, the content of each of which are incorporated herein by reference in their entireties.

### FIELD OF THE INVENTION

The present invention relates to a method for monitoring a battery and to a system for carrying out the method.

### BACKGROUND

A battery represents an interconnection of multiple galvanic cells, which is used as an energy store, for example in motor vehicles. In motor vehicles, batteries are used in particular for providing a supply voltage for the vehicle electrical system. Since batteries are subject to aging and wear processes, it is necessary to monitor these in order to ensure the functional capability necessary for a safe operation of the motor vehicle.

Methods which identify the aging of the battery are known. Aging of a battery is understood to mean that battery-specific performance characteristics such as capacity and high current capability decline or deteriorate due to gradual changes within the battery. These changes take place slowly over the course of weeks or even months and may be identified based on model-based approaches by parameter adjustments.

However, no methods are known which are able to identify a relatively suddenly occurring battery fault, such as a cell short circuit, in a timely manner, i.e., before failure of the battery performance capability. However, such a method is becoming increasingly important with respect to future driving scenarios, such as sailing, since in this case a sudden failure of the battery may result in a safety-critical situation. To avoid this situation, a timely identification, i.e., an identification of the occurrence of such a fault prior to the complete loss of power of the battery, is crucial.

The publication JP 2011 112 453 A describes a method for determining a cell short circuit of a battery by observing the behavior of the open circuit voltage, until it has reached its end value. If this change in the open circuit voltage exceeds a certain value during this time period, a cell short circuit is identified.

However, precisely this case may result in misinterpretations in the case of prior charging and at lower temperatures. In addition, the behavior of the voltage in the open circuit phase is very dependent on the previous history. Furthermore, it is not possible to safely distinguish between a high self-discharge and an actual cell short circuit.

The publication JP 2010 256 210 A describes a method in which a cell short circuit in absorbent glass mat (AGM) batteries is detected by the evaluation of the open circuit voltage in the fully charged state. This method is also drastically limited in the state of the detection. Furthermore, it is not always safely possible to distinguish the cell short circuit from strong sulfation.

### SUMMARY

According to an example embodiment of the present invention, a method for monitoring a battery allows an identification of a short circuit or of other damage, such as the loss of the contact of one or multiple plates of a cell. The method is used, for example, in a lead acid battery, such as a lead acid vehicle battery. The method avoids the disadvantages described in connection with the related art at least in several of the embodiments. Additionally, it is possible with the aid of the described method to establish the presence of a cell short circuit in an active phase of the battery.

The method is based on the evaluation of various measurable or estimatable variables of the battery, for example a lead battery, such as the peak voltage Uₚₑₐₖ during the starting process, the ohmic internal resistance Rᵢ of a battery or the current I_{batt} during charging using a constant voltage. These variables behave in a characteristic manner when a cell short circuit is present. Reference is made in this regard to FIG. 3. Depending on the configuration of the present short circuit or as a function of the number of plates which are no longer connected, these change more or less quickly.

The peak voltage Uₚₑₐₖ during starting and the internal resistance Rᵢ initially change slowly in a linear manner, or remain constant, and toward the end of the service life of the cell affected by the short circuit have a usually exponential increase. The current during constant voltage charging and at a constant temperature has either an increase or an unusually high constant portion.

This behavior can be utilized to arrive at a decision, with the aid of an algorithm, as to whether or not an internal short circuit is present.

For this purpose, the possible variables are mathematically analyzed in their behavior over time. For example, in an example embodiment, the analysis used a suitable filter, such as an RLS filter, a Kalman filter, or a predictive filter.

According to an example embodiment, the analysis is performed using a sliding window, which tracks the development of the values of these variables over a limited time or in a limited number, is also possible. The analysis with the aid of a sliding window means that a time segment or a window of the chronological progression is examined. For example, an increase in the chronological progression is ascertained during this segment or window. The algorithm in this case is the derivation of the curve representing the chronological progression. It is also possible to ascertain a straight line with the aid of regression for a derivation at multiple points in the time window. Moreover, a so-called least squares (RLS) algorithm can be applied.

It is advantageous that a certain averaging or filtering be present so that natural fluctuations or fluctuations not attributable to the error to be detected are not misinterpreted.

Furthermore, it can be important to standardize the values of these variables, if necessary, in order to ensure the comparability of the analyzed values. For example, the ohmic internal resistance Rᵢ changes as a function of the temperature, charge state, and sometimes even the previous history and aging of the battery. In order not to interpret this change erroneously as an indication of a battery defect then, these values for the internal resistance should be standardized to a certain operating point of the battery, e.g., 100% charged battery at 25° C.

As soon as these values or the trend of the value of one of these characteristic variables ascertained by the increase, e.g., Rᵢ, exceed(s) a certain established threshold value, a short circuit or another sudden battery fault is identified. This value to be evaluated can be a percentage or an absolute value, and accordingly, the threshold values are percentage values or absolute values, respectively.

To avoid a possible misinterpretation, i.e., to increase the robustness of the algorithm, it is advantageous to consider the behavior of not only one variable separately, but in connection with at least one other variable characteristic of a battery fault. This can be, e.g., the indication of a strong increase in the value of the peak voltage during the start, coupled with an average increase in the internal resistance.

However, example embodiments also facilitate, in the case of non-starting vehicles, such as with an electric vehicle, an identification of such a battery fault in a timely manner, where it is also possible to identify a defect even based only on the internal resistance or the charging at constant voltage.

To furthermore increase the robustness of the algorithm and exclude an incorrect decision, which should be avoided, in an example embodiment, in the case of the decision-making process based on the values of the characteristic variables Uₚₑₐₖ and Rᵢ, the behavior of the current integral is simultaneously analyzed in order to prevent the behavior of this variable due to a strong discharge from being attributed to a battery cell defect without factual reason. For this purpose, the current integral is calculated and evaluated in a time period relevant for the identification. As long as the value of this integral remains above a threshold value Ah_sum_threshold to be defined, a decision in favor of a cell short circuit can be made if needed. Reference is made in this regard to FIG. 2.

To arrive at a decision, decision trees including if-then branches are an option. Another option is to use fuzzy logic or neural networks for this purpose.

Further advantages and embodiments of the present invention are derived from the description and the accompanying drawings.

The above-mentioned features and those still to be described hereafter can be used not only in the particular described combination, but also in other combinations, or alone, without departing from the scope of the present invention.

### BRIEF DESCRIPTION OF THE DRAWINGS

FIG. 1 shows a logic flow of an evaluation of values of a characteristic variable in a method according to an example embodiment of the present invention.

FIG. 2 shows a logic flow of a decision-making process according to an example embodiment of the present invention.

FIG. 3 is a chart including a possible progression of a characteristic variable for a cell short circuit, Rᵢ here, in the event of a fault and the progression of the identification variable based thereon, according to an example embodiment of the present invention.

FIG. 4 shows a representation of a motor vehicle according to an example embodiment of the present invention.

### DETAILED DESCRIPTION

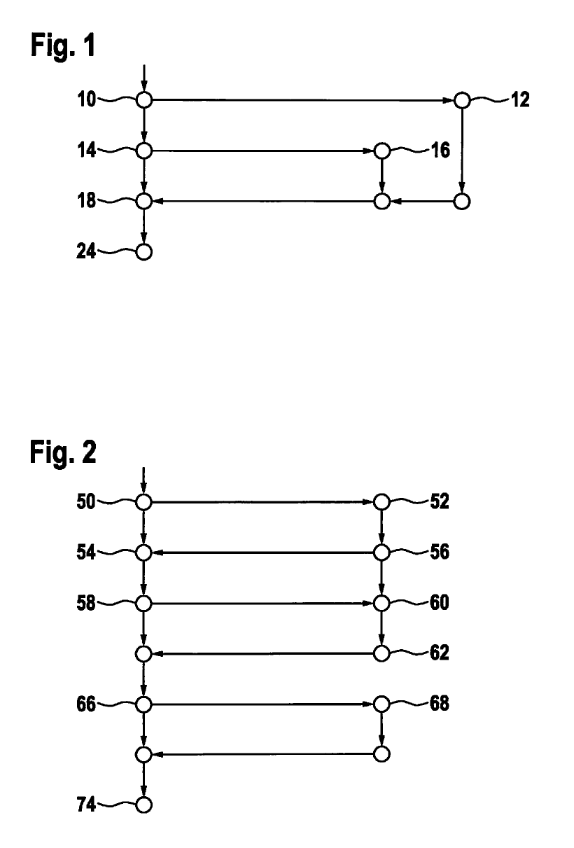

The present invention is schematically represented in the drawings based on example embodiments and is described in greater detail hereafter with reference to the drawings. FIG. 1 shows one specific embodiment of the logic of the evaluation of the values of a characteristic variable in a schematic representation.

In a first step 10, a derived variable, for example the derivation of a chronological progression at one or multiple points, is compared to a first threshold value. When this value is exceeded, a diagnosis value is set to 2. This means that an error is present in any case (point 12).

If the threshold value is not exceeded, in a next step 14 a comparison of the derived variable to a second threshold value takes place, and the comparison of an absolute value of the chronological progression, which can also be formed by an average value, to a third threshold value takes place. If the second threshold value or the third threshold value is exceeded, the diagnosis value is set to 1 (point 16). This means that an error is possibly present.

If none of the two threshold values is exceeded, the diagnosis value is set to 0, i.e., no error is present (point 18). The query is completed with step 24.

FIG. 2 shows a diagram of the logic for the decision-making process, as it can be implemented in the context of the method. In a first step 50, it is checked whether a definite defect is present.

This can be checked by an increase in the internal resistance, for example. If a threshold value is exceeded in this regard, the definite defect is identified (point 52). Otherwise, an increase in the charging current is checked in a next step 54. If a threshold value is exceeded, a definite defect is identified (point 56). Otherwise, the internal resistance and the increase in the peak voltage are checked in a further step 58. If the internal resistance exceeds a threshold value, which points to a possible defect, and the increase in the peak voltage exceeds a threshold value, which also points to a possible defect, a definite defect is assumed (point 60). A short circuit is then detected (point 62).

Otherwise, it is checked in a step 66 whether the sum of the current integral is less than/equal to a threshold value. If this is the case (point 68), the diagnosis value is reset since the negative charge conversion could interfere with the identification. The query ends with step 74.

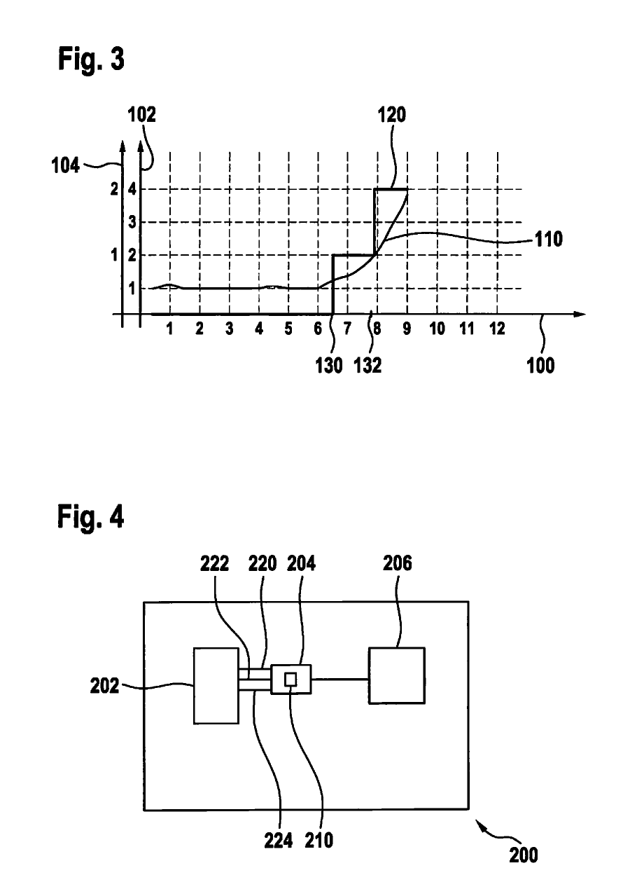

FIG. 3 shows a chart including a possible progression of a characteristic variable for a cell short circuit, Rᵢ here, in the event of an error and the progression of the diagnosis variable based thereon.

The time is plotted on an abscissa 100. The standardized value for the internal resistance is plotted on a first ordinate 102, and the value of the diagnosis variable is plotted on a second ordinate.

A first curve 110 shows the chronological progression of the standardized internal resistance. This progression is analyzed, from which at least one derived variable results, which in turn is compared to threshold values. This results in the values for the diagnosis variable, whose chronological progression is illustrated by a second curve 120. Initially, the value of the diagnosis variable is at 0. At a first point in time 130, it becomes 1, and at a second point in time 132 it becomes 2. This means that an error is present here in any case.

In the shown embodiment three values are provided for the diagnosis variable, namely 0 no error, 1 probably an error, and 2 definitely an error. However, it is also possible that only two values, namely 0 no error and 1 probably an error, are provided. Alternatively, more than three values can also be provided for the diagnosis variable, for example four, five, six or more.

In this way, different chronological progressions and different analyses or evaluations of the chronological progressions, if necessary also with different weighting, can be provided.

FIG. 4 shows an example embodiment of a motor vehicle denoted overall by reference numeral 200. It includes a battery 202, which is monitored by a battery sensor 204, which in turn communicates with a control unit 206. A system 210 for carrying out the method is provided in battery sensor 204. Battery sensor 204 can read in variables of the battery, in particular the chronological progression of variables, for carrying out the method. These can be an internal resistance 220, a peak voltage 222, and a current 224 for charging battery 202.

Introduced system 210 is configured to carry out a method of the type described above. This can be used in electronic battery sensor 204, but can also be situated as a separate component or also in control unit 206.

1-10. (canceled)

11. A method for monitoring a battery, the method comprising:
detecting, by a sensor, values of a variable of the battery over time;
analyzing, by a processor, mathematically, and based on the detected values, a behavior of the variable over time to obtain a value characterizing the behavior;
comparing, by the processor, the obtained value to a threshold value and thereby identifying an exceedance of the threshold value by the obtained value; and
identifying, by the processor and based on the identified exceedance, a fault of the battery.

12. The method of claim 11, wherein the variable is a peak voltage of the battery.

13. The method of claim 11, wherein the variable is an internal resistance of the variable.

14. The method of claim 11, wherein the variable is a current during a charging of the battery at a constant voltage.

15. The method of claim 11, wherein the battery is a lead acid battery.

16. The method of claim 11, wherein a filter is used for the mathematical analysis.

17. The method of claim 11, wherein a sliding window is used for the mathematical analysis.

18. The method of claim 11, wherein the variable is standardized.

19. A system for monitoring a battery, the system comprising:
a sensor; and
a processor, wherein the processor is configured to:
obtain from the sensor values, detected by the sensor, of a variable of the battery over time;
analyze, mathematically and based on the detected values, a behavior of the variable over time to obtain a value characterizing the behavior;
compare the obtained value to a threshold value and thereby identify an exceedance of the threshold value by the obtained value; and
identify, based on the identified exceedance, a fault of the battery.
